(19) United States
(12) Patent Application Publication
(10) Pub. No.: US 2026/0113981 A1
(43) Pub. Date: Apr. 23, 2026

(54) Double Gate Transistor and Display Device Including IT

(71) Applicant: LG Display Co., Ltd., Seoul (KR)

(72) Inventors: Minseong Yun, Paju-si (KR); Ahrum Sohn, Paju-si (KR)

(21) Appl. No.: 19/310,820

(22) Filed: Aug. 26, 2025

(30) Foreign Application Priority Data
Oct. 23, 2024 (KR) 10-2024-0145460

(51) Int. Cl. H10D 30/67; H10D 86/40; H10D 86/60; H10D 86/01

(52) U.S. Cl. CPC H10D 30/6734; H10D 30/6737; H10D 30/6757; H10D 86/441; H10D 86/60; H10D 86/0221

(57) ABSTRACT

The present disclosure provides a double gate transistor that includes a first gate electrode configured in an inverse taper shape on a first gate insulating layer, a buffer layer disposed to cover the first gate electrode, an active layer disposed on the buffer layer, a second gate insulating layer disposed to cover the active layer, and a second gate electrode configured in a taper shape on the second gate insulating layer, and a display device including the double gate transistor.

### CROSS REFERENCE TO RELATED APPLICATION

This application claims priority from Republic of Korea Patent Application No. 10-2024-0145460, filed on October 23, 2024, which is hereby incorporated by reference in its entirety.

### TECHNICAL FIELD

The present disclosure relates to a double gate transistor and a display device including the double gate transistor, and more particularly, to a double gate transistor having improved switching characteristics and a display device including the double gate transistor.

### BACKGROUND

In today's information society, display devices for presenting images or visual information to users are increasingly important. The need for such display devices has caused display technology to be rapidly developed, and various types of display devices, such as a liquid crystal display (LCD) device, a plasma display device, a quantum-dot light emitting display device, an organic light emitting display (e.g., OLED) device, an inorganic light emitting display device, and the like, have been developed and widely used.

Among these display devices, the organic light emitting display device has high response speed and has advantages in contrast ratio, emission efficiency, luminance, viewing angle, and the like, by using an organic light emitting diode (OLED), which is a self-emission element.

The organic light emitting display device may include organic light emitting diodes disposed in a plurality of subpixels disposed in a display panel, and can display images by light emitted from each subpixel through driving current flowing to each organic light emitting diode controlled by a corresponding driving transistor.

For example, one or more of transistors included in at least one subpixel may be oxide transistors. In this implementation, the oxide transistors may provide an advantage of reducing leakage current and preventing an image artifact such as flicker.

Further, the oxide transistors may be configured with a double gate structure including an upper gate electrode and a lower gate electrode to improve current characteristics and secure reliability.

However, when an upper interlayer insulating layer has a small thickness, a transistor with such a double gate structure may suffer from a seam defect occurring in a boundary area of an upper gate electrode of the transistor, and the degradation of switching characteristics as a channel width of an active layer is reduced.

### SUMMARY

To address these issues, inventors of the present disclosure have invented a double gate transistor having improved switching characteristics and a display device including the double gate transistor.

One or more embodiments of the present disclosure may provide a double gate transistor having a structure where an active layer has an increased channel width and thereby providing improved switching characteristics, and a display device including the double gate transistor.

One or more embodiments of the present disclosure may provide a double gate transistor having a structure including an upper gate electrode of a first taper shape and a lower gate electrode of a second taper shape and thereby providing an active layer with an increased channel width and improved switching characteristics, and a display device including the double gate transistor.

One or more embodiments of the present disclosure may provide a double gate transistor having a double taper structure of an upper gate electrode and a lower gate electrode through process optimization, and a display device including the double gate transistor.

According to one or more example embodiments of the present disclosure, a double gate transistor can be provided that includes a first gate electrode configured in an inverse taper shape on a first gate insulating layer, a buffer layer disposed to cover the first gate electrode, an active layer disposed on the buffer layer, a second gate insulating layer disposed to cover the active layer, and a second gate electrode configured in a taper shape on the second gate insulating layer.

According to one or more example embodiments of the present disclosure, a display device can be provided that includes a display panel in which a plurality of subpixels are disposed, a gate driving circuit configured to supply at least one gate signal to the display panel, a data driving circuit configured to supply at least one data signal to the display panel, a timing controller for controlling the gate driving circuit and the data driving circuit, each of the plurality of subpixels including a double gate transistor including a first gate electrode configured in an inverse taper shape on a first gate insulating layer, a buffer layer disposed to cover the first gate electrode, an active layer disposed on the buffer layer, a second gate insulating layer disposed to cover the active layer, and a second gate electrode configured in a taper shape on the second gate insulating layer.

According to one or more example embodiments of the present disclosure, a display device can be provided that includes a display panel in which a plurality of subpixels are disposed, a gate driving circuit configured to supply at least one gate signal to the display panel, a data driving circuit configured to supply at least one data signal to the display panel, a timing controller for controlling the gate driving circuit and the data driving circuit, the gate driving circuit including a double gate transistor including a first gate electrode configured in an inverse taper shape on a first gate insulating layer, a buffer layer disposed to cover the first gate electrode, an active layer disposed on the buffer layer, a second gate insulating layer disposed to cover the active layer, and a second gate electrode configured in a taper shape on the second gate insulating layer.

According to one or more embodiments of the present disclosure, a double gate transistor having improved switching characteristics and a display device including the double gate transistor may be provided.

According to one or more aspects of the present disclosure, a double gate transistor and a display device including the double gate transistor may be provided that have a structure where an active layer has an increased channel width, and thereby provide improved switching characteristics.

According to one or more embodiments of the present disclosure, a double gate transistor and a display device including the double gate transistor may be provided that have a structure including an upper gate electrode of a first taper shape and a lower gate electrode of a second taper shape. and thereby provide an active layer with an increased channel width and improved switching characteristics.

According to one or more embodiments of the present disclosure, a double gate transistor and a display device including the double gate transistor may be provided that have a double taper structure of an upper gate electrode and a lower gate electrode through process optimization.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example display device according to embodiments of the present disclosure;

FIG. 2 illustrates an example system of the display device according to embodiments of the present disclosure;

FIG. 3 illustrates an example subpixel circuit of the display device according to embodiments of the present disclosure;

FIG. 4 schematically illustrates an example gate driving circuit configured to generate at least one gate signal in the display device according to embodiments of the present disclosure;

FIG. 5 illustrates an example configuration of the gate driving circuit in the display device according to embodiments of the present disclosure;

FIG. 6 illustrates an example gate driving integrated circuit configured to output at least one scan signal in the display device according to embodiments of the present disclosure;

FIG. 7 is an example plan view of a double gate transistor included in the display device according to embodiments of the present disclosure;

FIG. 8 is an example cross-sectional view of the double gate transistor taken along line A-B in FIG. 7, in the display device according to embodiments of the present disclosure;

FIGS. 9 to 13 illustrate an example process of manufacturing a double gate transistor included in the display device according to embodiments of the present disclosure;

FIG. 14 illustrates an example process of forming a first gate electrode of a single layer structure in an inverse taper shape in a double gate transistor according to embodiments of the present disclosure;

FIG. 15 illustrates an example process of forming a first gate electrode of a double layer structure in an inverse taper shape in a double gate transistor according to embodiments of the present disclosure;

FIG. 16 illustrates an example process of forming a first gate electrode of a triple layer structure in an inverse taper shape in a double gate transistor according to embodiments of the present disclosure;

FIG. 17 illustrates an example structure of a double gate transistor including an active layer of a triple layer structure according to embodiments of the present disclosure; and

FIG. 18 illustrates another example structure of a double gate transistor including an active layer of a triple layer structure according to embodiments of the present disclosure.

### DETAILED DESCRIPTION

Hereinafter, some embodiments of the present disclosure will be described in detail with reference to exemplary drawings. Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element may be included in at least one of two or more elements that "are connected or coupled to", “contact or overlap”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to the accompanying drawings.

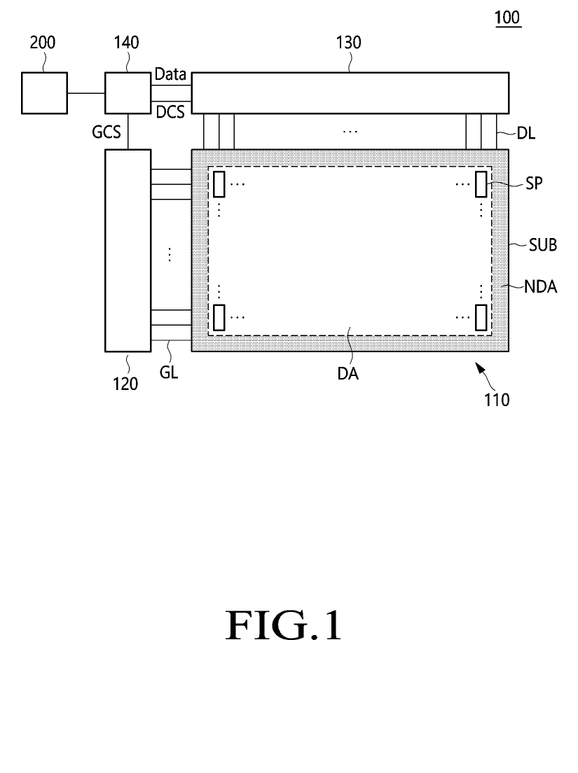

FIG. 1 illustrates an example display device according to aspects of the present disclosure.

Referring to FIG. 1, in one or more example embodiments, a display device 100 may include a display panel 110 and at least one driving circuit for driving the display panel 110.

The display panel 110 may include a display area DA in which an image can be displayed and a non-display area NDA in which an image is not displayed. The non-display area NDA may also be referred to as a non-active area, a bezel, or a bezel area.

The display panel 110 may include a plurality of subpixels SP for image displaying. For example, the plurality of subpixels SP may be disposed in the display area DA. In one or more aspects, at least one subpixel SP may be disposed in the non-display area NDA. The at least one subpixel SP disposed in the non-display area NDA may be referred to as a dummy subpixel.

The display panel 110 may include a plurality of signal lines for driving the plurality of subpixels SP. For example, the plurality of signal lines may include a plurality of data lines DL and a plurality of gate lines GL. The signal lines may further include other signal lines, in addition to the plurality of data lines DL and the plurality of gate lines GL, according to the structure of the subpixels SP. For example, such signal lines may include drive voltage lines, reference voltage lines, and the like.

The plurality of data lines DL and the plurality of gate lines GL may intersect each other. Each of the plurality of data lines DL may extend in a first direction. Each of the plurality of gate lines GL may extend in a second direction different from the first direction. For example, the first direction may be a column or vertical direction, and the second direction may be a row or horizontal direction. Herein, the column direction and the row direction may not represent absolute directions, but may represent relative directions. For example, the column direction may be the vertical direction and the row direction may be the horizontal direction. In another example, the column direction may be the horizontal direction and the row direction may be the vertical direction.

The at least one driving circuit may include a data driving circuit 130 for driving a plurality of data lines DL and a gate driving circuit 120 for driving a plurality of gate lines GL. The at least one driving circuit may further include a timing controller 140 for controlling the data driving circuit 130 and the gate driving circuit 120.

The data driving circuit 130 may be a circuit for driving the plurality of data lines DL and can output data signals (which may be referred to as data voltages) corresponding to image signals to the plurality of data lines DL. The gate driving circuit 120 may be a circuit for driving the plurality of gate lines GL and can generate gate signals and supply the generated gate signals to the plurality of gate lines GL. The gate signals may include at least one scan signal and at least one light emission signal.

The timing controller 140 can start to scan pixels according to respective timings set in each frame, and can control data driving at timings set for scanning corresponding one or more of the pixels. The timing controller 140 can convert image data received from an external device or system (e.g., a host system 200) to a data signal form readable by the data driving circuit 130, and then supply image data Data resulting from the converting to the data driving circuit 130.

The timing controller 140 can receive display driving control signals along with image data from the external host system 200. For example, the display driving control signals may include a vertical sync signal, a horizontal sync signal, an input data enable signal, a clock signal, and the like.

The timing controller 140 can generate data driving control signals DCS and gate driving control signals GCS based on the display driving control signals received from the host system 200. The timing controller 140 can control the driving operation and driving timing of the data driving circuit 130 by supplying the data driving control signals DCS to the data driving circuit 130. The timing controller 140 can control the driving operation and driving timing of the gate driving circuit 120 by supplying the gate driving control signals GCS to the gate driving circuit 120.

The data driving circuit 130 may include one or more source driving integrated circuits SDIC. Each source driving integrated circuit SDIC may include a shift register, a latch circuit, a digital to analog converter, an output buffer, and the like. In one or more aspects, each source driving integrated circuit SDIC may further include an analog-to-digital converter (ADC).

In one or more embodiments, each source driving integrated circuit SDIC may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

The gate driving circuit 120 can supply a gate signal of a turn-on level voltage, a gate signal of a turn-off level voltage, or a gate signal with a turn-on level and a turn-off level according to the control of the timing controller 140. The gate driving circuit 120 can sequentially drive a plurality of gate lines GL by sequentially supplying gate signals of the turn-on level voltage to the plurality of gate lines GL.

The gate driving circuit 120 may include one or more gate driving integrated circuits GDIC.

In one or more embodiments, the gate driving circuit 120 may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. However, embodiments of the present disclosure are not limited thereto. In one or more embodiments, the gate driving circuit 120 included in the display device 100 may be disposed in the non-display area NDA of the display panel 110 by a gate-in-panel (GIP) technique. The gate driving circuit 120 may be disposed on a substrate, or connected to the substrate. In an example where the gate driving circuit 120 is implemented in the display device 100 by the gate-in-panel (GIP) technique, the gate driving circuit 120 may be disposed in the non-display area NDA of the substrate. In one or more aspects, the gate driving circuit 120 may be connected to the substrate when the gate driving circuit 120 is implemented by the chip-on-glass (COG) technique, the chip-on-film (COF) technique, or the like.

In one or more embodiments, at least one of the data driving circuit 130 and the gate driving circuit 120 may be disposed in the display area DA. For example, at least one of the data driving circuit 130 and the gate driving circuit 120 may be disposed not to overlap with subpixels SP, or be disposed to overlap with one or more, or all, of the subpixels SP.

The data driving circuit 130 may be located in, and/or electrically connected to, but not limited to, only one side or edge (e.g., an upper portion or a lower portion) of the display panel 110. In one or more embodiments, the data driving circuit 130 may be disposed in, and/or electrically connected to, but not limited to, two sides or edges (e.g., an upper portion and a lower portion) of the display panel 110 or more than two of four sides or edges (e.g., the upper portion, the lower portion, a left portion, and a right portion) of the display panel 110 according to driving schemes, panel design schemes, or the like.

The gate driving circuit 120 may be located in, and/or electrically connected to, but not limited to, only one side or edge (e.g., a left portion or a right portion) of the display panel 110. In one or more aspects, the gate driving circuit 120 may be disposed in, and/or electrically connected to, but not limited to, two sides or edges (e.g., a left portion and a right portion) of the display panel 110 or more than two of four sides or edges (e.g., the left portion, the right portion, an upper portion, and a lower portion) of the display panel 110 according to driving schemes, panel design schemes, or the like.

The timing controller 140 may be implemented in a separate component from the data driving circuit 130, or integrated with the data driving circuit 130, so that the timing controller 140 and the data driving circuit 130 can be implemented in a single integrated circuit. The timing controller 140 may be a controller used in the typical display technology or a control apparatus/device capable of additionally performing other control functionalities in addition to the typical function of the timing controller. In one or more embodiments, the timing controller 140 may be one or more other control circuits different from the timing controller, or a circuit or component in the control apparatus/device. The timing controller 140 may be implemented with various circuits or electronic components such as an integrated circuit (IC), a field programmable gate array (FPGA), an application specific integrated circuit (ASIC), a processor, and/or the like.

The timing controller 140 may be mounted on a printed circuit board, a flexible printed circuit, or the like, and may be electrically connected to the data driving circuit 130 and the gate driving circuit 120 through the printed circuit board, the flexible printed circuit, and/or the like. The timing controller 140 can transmit signals to, and receive signals from, the data driving circuit 130 via one or more predetermined interfaces. For example, such interfaces may include a low voltage differential signaling (LVDS) interface, an embedded clock point-point interface (EPI), a serial peripheral interface (SPI), and the like.

In one or more embodiments, the display device 100 may be a liquid crystal display device, a self-emission display device in which light is emitted from the display panel 110 itself, or the like. In an example where the display device 100 is a self-emission display device, each of the plurality of subpixels SP included in the display device 100 may include a light emitting element such as an organic light emitting diode, an inorganic light emitting diode, a quantum dot light emitting diode, a micro light emitting diode, a mini light emitting diode, or the like. In one or more embodiments, the display device 100 may be an organic light emitting display device in which the light emitting element is implemented using an organic light emitting diode (OLED). In one or more embodiments, the display device 100 may be an inorganic light emitting display device in which the light emitting element is implemented using an inorganic material-based light emitting diode. In one or more aspects, the display device 100 may be a quantum dot display device in which the light emitting element is implemented using quantum dots, which are self-emission semiconductor crystals.

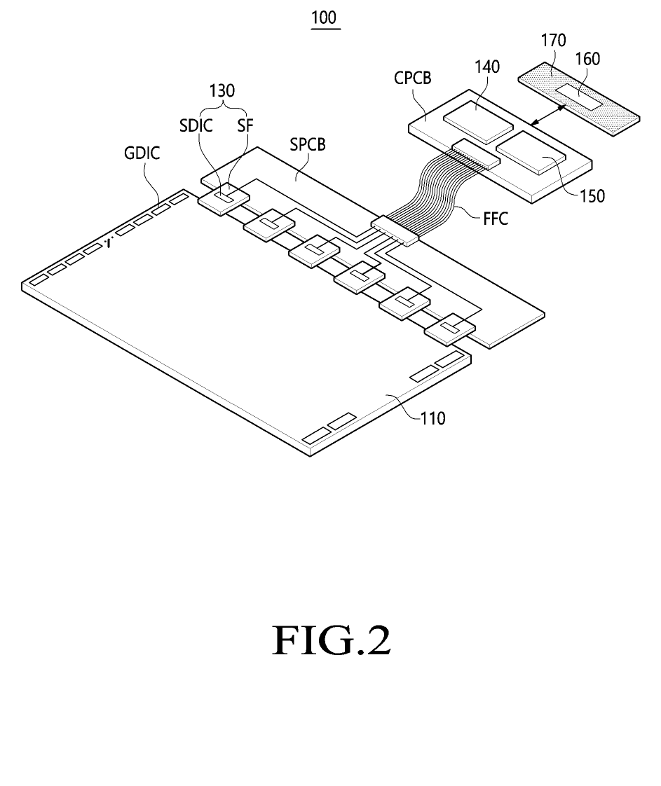

FIG. 2 illustrates an example system of the display device 100 according to embodiments of the present disclosure.

Referring to FIG. 2, in one or more example embodiments, the data driving circuit 130 and the gate driving circuit 120 included in the display device 100 may be implemented by the chip-on-film (COF) technique and the gate-in-panel (GIP) technique, respectively, among various techniques such as the tape-automated-bonding (TAB) technique, the chip-on-glass (COG) technique, the chip-on-film (COF) technique, and the like.

In an example where the gate driving circuit 120 is implemented by the GIP technique, a plurality of gate driving integrated circuits GDIC included in the gate driving circuit 120 may be disposed directly in the non-display area NDA of the display panel 110. In this example, the gate driving integrated circuits GDIC can receive various types of signals (e.g., clock signals, gate high signals, gate low signals, and the like) needed for generating scan signals through gate driving-related signal lines disposed in the non-display area NDA.

In one or more embodiments, one or more source driving integrated circuits SDIC included in the data driving circuit 130 may be mounted on one or more respective source films SF, and one side of each source film SF may be electrically connected to the display panel 110. In one or more embodiments, lines for electrically connecting the one or more source driving integrated circuits SDIC and the display panel 110 may be respectively disposed in upper portions of the one or more source films SF.

The display device 100 may include at least one source printed circuit board SPCB for circuital connections between the one or more source driving integrated circuits SDIC and other units or devices, and a control printed circuit board CPCB for mounting control components and several types of electrical units or devices.

In one or more embodiments, one side of a source film SF on which a source driving integrated circuit SDIC is mounted may be connected to the at least one source printed circuit board SPCB. For example, one side of the source film SF on which the source driving integrated circuit SDIC is mounted may be electrically connected to the at least one source printed circuit board SPCB, and the other side thereof may be electrically connected to the display panel 110.

The timing controller 140 and the power management circuit 150 may be mounted on the control printed circuit board CPCB. The timing controller 140 can control operations of the data driving circuit 130 and the gate driving circuit 120. The power management circuit 150 can supply various levels of voltages or currents to the display panel 110, the gate driving circuit 120, the data driving circuit 130, and the like, or control various levels of voltages or currents to be supplied.

The at least one source printed circuit board SPCB and the control printed circuit board CPCB may be electrically connected to each other through at least one connector, such as a flexible printed circuit FPC, a flexible flat cable FFC, and/or the like. In one or more aspects, the at least one source printed circuit board SPCB and the control printed circuit board CPCB may be integrated into one printed circuit board.

The display device 100 may further include a set board 170 electrically connected to the control printed circuit board CPCB. The set board 170 may be referred to as a power board. A main power management circuit 160 configured to manage the entire power of the display device 100 may be mounted on the set board 170. The main power management circuit 160 may interoperate with the power management circuit 150.

In the example where the display device 100 includes the power management circuit 150, the set board 170, the control printed circuit board CPCB, and the like as described above, one or more driving voltages generated by the set board 170 may be transmitted to the power management circuit 150 of the control printed circuit board CPCB. The power management circuit 150 may transmit one or more driving voltages needed for display driving or characteristic value sensing to the source printed circuit board SPCB through the flexible printed circuit FPC or the flexible flat cable FFC. One or more driving voltages transmitted to the source printed circuit board SPCB may be supplied to the display panel 110 through one or more source driving integrated circuits SDIC, and used to enable one or more specific subpixels SP to emit light or sense one or more subpixels SP.

In one or more embodiments, each subpixel SP included in the display panel 110 of the display device 100 may include circuit elements, such as a light emitting element (e.g., an organic light emitting diode OLED), a driving transistor for driving the light emitting element, and the like.

Types of circuit elements and the number of the circuit elements included in each subpixel SP may be different depending on types of the panel (e.g., an LCD panel, an OLED panel, etc.), provided functions, design schemes/features, or the like.

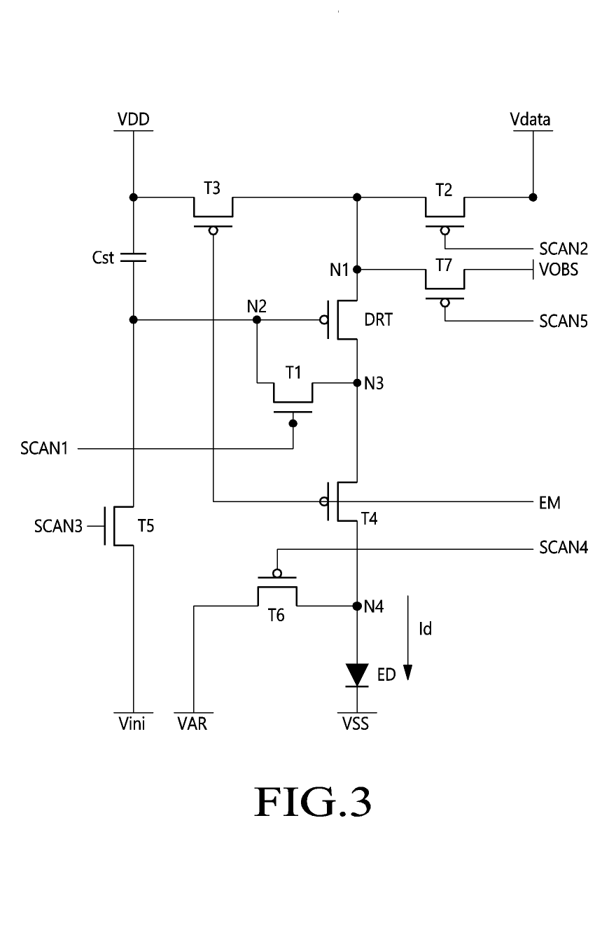

FIG. 3 illustrates an example subpixel circuit of the display device 100 according to aspects of the present disclosure.

Referring to FIG. 3, in one or more example embodiments, each, or one or more, of a plurality of subpixels SP included in the display device 100 may include first to seventh switching transistors (T1 to T7), a driving transistor DRT, a storage capacitor Cst, and a light emitting element ED.

In one or more embodiments, the light emitting element ED may be a self-emission element, such as an organic light emitting diode (OLED), an inorganic light emitting diode, a quantum dot light emitting diode, a micro light emitting diode, a mini light emitting diode, or the like.

In one or more embodiments, the second to fourth switching transistors (T2 to T4), the sixth switching transistor T6, and the seventh switching transistor T7 may be P-type transistors. In one or more embodiments, the first switching transistor T1 and the fifth switching transistor T5 may be N-type transistors.

The driver transistor DRT may be either a P-type or an N-type transistor. It should be noted here that FIG. 3 illustrates a P-type of driving transistor DRT as an example, but aspects of the present disclosure are not limited thereto.

P-type transistors are relatively more reliable than N-type transistors. In the example where the P-type of driving transistor DRT is used, since a high driving voltage VDD can be applied fixed or constantly to its source electrode when the light emitting element ED is driven to emit light, the application of the P-type of driving transistor DRT can provide advantages of preventing or at least reducing current flowing to the light emitting element ED from fluctuating due to the capacitor Cst. Therefore, the driving transistor DRT can provide stably current for driving the light emitting element ED.

When the P-type of driving transistor DRT operates in a saturation region in a configuration where the P-type of driving transistor DRT is connected to an anode electrode of the light emitting element ED, the P-type of driving transistor DRT can provide a constant current to the light emitting element ED regardless of a change in a threshold voltage, and thus, have the characteristic of relatively high reliability.

In the subpixel circuit based on the configurations discussed above, the N-type transistors may be oxide transistors formed using an oxide semiconductor, for example, transistors having a channel formed from an oxide semiconductor such as indium oxide, gallium oxide, zinc oxide, indium gallium zinc oxide (IGZO), indium gallium zinc tin oxide (IGZTO), or the like. The P-type transistor may be silicon transistors formed using a semiconductor such as silicon, for example, transistors having a polysilicon channel formed by a low-temperature process referred to as LTPS or low-temperature polysilicon.

The oxide transistors may have the characteristic of relatively lower leakage current than silicon transistors.

Taking account of these characteristics, driving transistors DRT or at least part of switching transistors included in subpixels SP may be oxide transistors.

For example, the first switching transistor T1 connected to the gate electrode of the driving transistor DRT, and the fifth switching transistor T5 may be oxide transistors.

For example, the driving transistor DRT and the remaining switching transistors (T2, T3, T4, T6 and T7) may be low-temperature polysilicon transistors.

According to these examples, each, or one or more, of the subpixel SP included in the display device 100 may include a first group of switching transistors (T1 and T5), which are oxide transistors, and the driving transistor DRT and a second group of switching transistors (T2, T3, T4, T6, and T7), which are low-temperature polysilicon transistors.

As the first group of switching transistors (T1 and T5) implemented as an oxide transistor are used, the display device 100 can provide an effect or advantage of preventing leakage current from flowing to the gate electrode of the driving transistor DRT, and thereby, reducing or eliminating undesirable image artifacts such as flicker and the like.

In one or more embodiments, to improve current characteristics in a turn-on state and provide high reliability, the first group of switching transistors (T1 and T5) may have a double gate structure including an upper gate electrode and a lower gate electrode .

It should be noted that the source electrode and the drain electrode of the switching transistors may be referred to as the drain electrode and the source electrode, respectively, depending on an input voltage.

A first scan signal SCAN1 may be applied to the gate electrode of the first switching transistor T1. A second electrode (e.g., the drain electrode) of the first switching transistor T1 may be connected to the gate electrode N2 of the driving transistor DRT. A first electrode (e.g., the source electrode) of the first switching transistor T1 may be connected to a second electrode (e.g., the drain electrode) N3 of the driving transistor DRT.

The first switching transistor T1 may be turned on by the first scan signal SCAN1 and form a current path between the gate electrode N2 and the second electrode N3 of the driving transistor DRT by a storage capacitor Cst with one electrode to which a high driving voltage VDD is fixedly applied.

The first switching transistor T1 may be an N-type MOS transistor implemented as an oxide transistor. Since the N-type MOS transistor uses, as carriers, electrons rather than holes, the N-type MOS transistor can provide carrier mobility faster than the P-type MOS transistor and thus provide a faster switching speed.

In one or more embodiments, the first switching transistor T1 may have a double gate structure to reduce or eliminate leakage current due to charge injection while the display device 100 is driven to display an image.

A second scan signal SCAN2 may be applied to the gate electrode of the second switching transistor T2. A data voltage Vdata may be supplied to a first electrode (e.g., the source electrode) of the second switching transistor T2. A second electrode (e.g., the drain electrode) of the second switching transistor T2 may be connected to a first electrode (e.g., the source electrode) N1 of the driving transistor DRT. The second switching transistor T2 may be turned on by the second scan signal SCAN2 and allow the data voltage Vdata to be passed to the first electrode (e.g., the source electrode) N1 of the driving transistor DRT.

In a state where the first switching transistor T1 is turned on, as the data voltage Vdata is supplied to the first electrode (e.g., the source electrode) N1 of the driving transistor DRT through the second switching transistor T2, a difference (Vdata-Vth) between the data voltage Vdata and a threshold voltage Vth of the driving transistor DRT can be sampled and supplied to the gate electrode N2 of the driving transistor DRT. According to this operation, the first switching transistor T1 may be referred to as a sampling transistor, and the first scan signal SCAN1 may be referred to as a sampling scan signal.

An emission signal EM may be applied to the gate electrode of the third switching transistor T3. The high driving voltage VDD may be applied to a first electrode (e.g., the source electrode) of the third switching transistor T3. A second electrode (e.g., the drain electrode) of the third switching transistor T3 may be connected to the first electrode (e.g., the source electrode) N1 of the driving transistor DRT. The third switching transistor T3 may be turned on by the emission signal EM and allow the high driving voltage VDD to be passed to the first electrode (e.g., the source electrode) N1 of the driving transistor DRT.

The emission signal EM may be applied to the gate electrode of the fourth switching transistor T4. A first electrode (e.g., the source electrode) of the fourth switching transistor T4 may be connected to the second electrode (e.g., the drain electrode) N3 of the driving transistor DRT. A second electrode (e.g., the drain electrode) of the fourth switching transistor T4 may be connected to the anode electrode N4 of the light emitting element ED. The fourth switching transistor T4 may be turned on by the emission signal EM and allow a driving current Id to flow to the anode electrode N4 of the light emitting element ED.

A third scan signal SCAN3 may be applied to the gate electrode of the fifth switching transistor T5. For example, the third scan signal SCAN3 may be a signal having a phase different from a first scan signal SCAN1 applied to another subpixel SP at a different location from the subpixel SP to which the third scan signal SCAN3 is applied. For example, when the first scan signal SCAN1 is applied to a nth gate line, the third scan signal SCAN3 may be supplied using a first scan signal SCAN1 applied to an (n-1)th gate line. For example, the third scan signal SCAN3 may be supplied by using the first scan signal SCAN1 delivered through a different gate line GL according to a phase at which the display panel 110 is driven.

An initialization voltage Vini may be applied to a second electrode (e.g., the drain electrode) of the fifth switching transistor T5. A first electrode (e.g., the source electrode) of the fifth switching transistor T5 may be connected to the gate electrode N2 of the driving transistor DRT and the storage capacitor Cst. The fifth switching transistor T5 may be turned on by the third scan signal SCAN3 and allow the initialization voltage Vini to be applied to the gate electrode N2 of the driving transistor DRT. According to this operation, the fifth switching transistor T5 may be referred to as an initialization transistor, and the third scan signal SCAN3 may be referred to as an initialization scan signal.

In one or more embodiments, the fifth switching transistor T5 may have a double-gate structure to reduce or eliminate leakage current due to charge injection while the display device 100 is driven to display an image.

A fourth scan signal SCAN4 may be applied to the gate electrode of the sixth switching transistor T6. A reset voltage VAR may be applied to a first electrode (e.g., the source electrode) of the sixth switching transistor T6. A second electrode (e.g., the drain electrode) of the sixth switching transistor T6 may be connected to the anode electrode N4 of the light emitting element ED. The sixth switching transistor T6 may be turned on by the fourth scan signal SCAN4 and allow the reset voltage VAR to be passed to the anode electrode N4 of the light emitting element ED.

A fifth scan signal SCAN5 may be applied to the gate electrode of the seventh switching transistor T7. A bias voltage VOBS may be applied to a first electrode (e.g., the source electrode) of the seventh switching transistor T7. A second electrode (e.g., the drain electrode) of the seventh switching transistor T7 may be connected to the first electrode (e.g., the source electrode) N1 of the driving transistor DRT.

For example, the fifth scan signal SCAN5 may be a signal having a phase different from a third scan signal SCAN3 applied to another subpixel SP at a different location from the subpixel SP to which the fifth scan signal SCAN5 is applied. For example, when the third scan signal SCAN3 is applied to an nth gate line, the fifth scan signal SCAN5 may be supplied using a third scan signal SCAN3 applied to an (n-1)th gate line. For example, the fifth scan signal SCAN5 may be supplied by using the third scan signal SCAN3 delivered through a different gate line GL according to a phase at which the display panel 110 is driven.

Since the fifth scan signal SCAN5 is a signal for applying the bias voltage VOBS to the driving transistor DRT, the fifth scan signal SCAN5 may be required to be different from the second scan signal SCAN2 for applying a data voltage Vdata.

The gate electrode N2 of the driving transistor DRT may be connected to the second electrode (e.g., the drain electrode) of the first switching transistor T1. The first electrode (e.g., the source electrode) N1 of the driving transistor DRT may be connected to the second electrode (e.g., the drain electrode) of the second switching transistor T2. The second electrode (e.g., the drain electrode) N3 of the driving transistor DRT may be connected to the first electrode (e.g., the source electrode) of the first switching transistor T1.

The driving transistor DRT may be turned on by a difference in voltage between the gate electrode N2 and the first electrode (e.g., the source electrode) N1, and can supply a driving current Id to the light emitting element ED.

The first electrode (e.g., the source electrode) and the second electrode (e.g., the drain electrode) of the first switching transistor T1 may be connected to the second electrode (e.g., the drain electrode) N3 and the gate electrode N2 of the driving transistor DRT, respectively. In a state where the first switching transistor T1 is turned on, the operations of sampling, and compensating for, a threshold voltage of the driving transistor DRT may be performed by a data voltage Vdata applied to the first electrode (e.g., the source electrode) N1 of the driving transistor DRT.

One side or electrode of the storage capacitor Cst may be applied with the high driving voltage VDD, and the other side or electrode thereof may be connected to the gate electrode N2 of the driving transistor DRT. The storage capacitor Cst can store a voltage at the gate electrode N2 of the driving transistor DRT.

The anode electrode N4 of the light emitting element ED may be connected to the second electrode (e.g., the drain electrode) of the fourth switching transistor T4 and the second electrode (e.g., the drain electrode) of the sixth switching transistor T6. A base voltage VSS with a low level of voltage may be applied to a cathode electrode of the light emitting element ED.

The light emitting element ED can emit light at a predetermined luminescence by a driving current Id supplied by the driving transistor DRT.

In one or more aspects, the initialization voltage Vini may be supplied to stabilize a change in capacitance formed through the gate electrode N2 of the driving transistor DRT, and the reset voltage VAR may be supplied to reset the anode electrode N4 of the light emitting element ED.

In a state where the fourth switching transistor T4, which is located between the anode electrode N4 of the light emitting element ED and the second electrode (e.g., the drain electrode) N3 of the driving transistor DRT and controlled by the emission signal EM, is turned off, the anode electrode N4 of the light emitting element ED can be reset when the reset voltage VAR is supplied to the anode electrode N4 of the light emitting element ED.

The sixth switching transistor T6 for supplying the reset voltage VAR may be connected to the anode electrode N4 of the light emitting element ED.

To enable the driving operation of the driving transistor DRT and the resetting operation of the anode electrode N4 of the light emitting element ED to be performed separately, the third scan signal SCAN3 for driving and/or initializing the driving transistor DRT and the fourth scan signal SCAN4 for controlling the supply of the reset voltage VAR to the anode electrode N4 of the light emitting element ED may be supplied as signals different from each other.

In one or more embodiments, when the switching transistors T5 and T6 for supplying the initialization voltage Vini and the reset voltage VAR are turned on, the fourth switching transistor T4 interconnecting the drain electrode N3 of the driving transistor DRT and the anode electrode N4 of the light emitting element ED may be turned off, and thereby, a driving current Id from the driving transistor DRT can be prevented from flowing to the anode electrode N4 of the light emitting element ED, and the anode electrode N4 can be prevented from being affected by any voltage other than the reset voltage VAR.

As in the illustration of FIG. 3, the subpixel circuit including eight transistors (DRT, T1, T2, T3, T4, T5, T6, and T7) and one storage capacitor Cst may be referred to as an 8T1C structure.

Herein, in one or more example embodiments, among subpixel circuits of various structures, the 8T1C structure may be applied to each, one or more, of subpixels SP included in the display device 110 as shown in FIG. 3 as an example, but the structure and number of transistors and capacitors included in the subpixel(s) SP may be changed according to design requirements. In one or more embodiments, each of a plurality of subpixels SP may have the same structure, or one or more of the plurality of subpixels SP may have a structure different from the remaining subpixels SP.

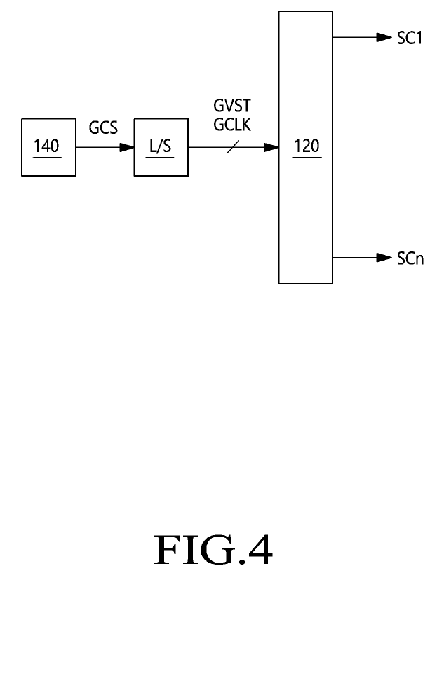

FIG. 4 schematically illustrates an example gate driving circuit configured to generate at least one gate signal in the display device 100 according to aspects of the present disclosure.

Referring to FIG. 4, in one or more example embodiments, the display device 100 may include the timing controller 140, a level shifter L/S, and the gate driving circuit 120.

The level shifter L/S can output a plurality of gate clock signals GCLK and a gate start signal GVST, and the like based on a gate control signal GCS output from the timing controller 140. The plurality of gate clock signals GCLK may be output in the form of signals with different phases, such as 2-phase, 4-phase, or 8-phase.

The gate driving circuit 120 can operate based on the gate clock signals GCLK and the gate start signal GVST output from the level shifter L/S, and output at least one gate signal for turning on or off transistors included in the display panel 110. The at least one gate signal may include scan signals (SC1-SCn), a sensing signal, an emission signal, or the like.

The level shifter L/S may be disposed in a separate integrated circuit, or may be included in the power management circuit 150 or in another device.

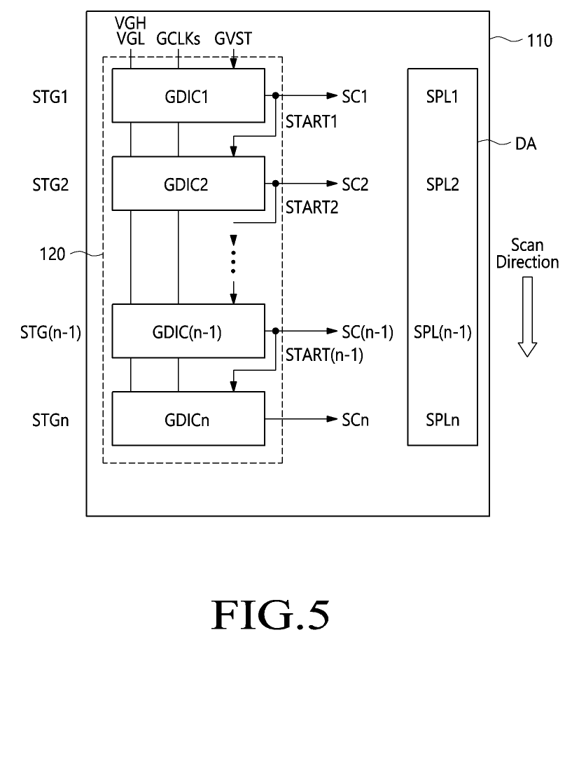

FIG. 5 illustrates an example configuration of the gate driving circuit 120 in the display device 100 according to aspects of the present disclosure.

Referring to FIG. 5, in one or more example embodiments, the gate driving circuit 120 included in the display device 100 may be disposed in at least one side bezel area of the display panel 110.

The gate driving circuit 120 may include n (where n is a natural number greater than or equal to 2) stages (STG1 to STGn) in which n gate driving integrated circuits (GDIC1 to GDICn) are connected in a cascade. The gate driving integrated circuits (GDIC1 to GDICn) each may be applied with a gate high voltage VGH and a gate low voltage VGL as driving voltages, and can operate by gate clock signals GCLKs.

A first gate driving integrated circuit GDIC1 can start operation by a gate start signal GVST, and a second gate driving integrated circuit GDIC2 to an nth gate driving integrated circuit GDICn can receive scan signals (SC1 to SC(n-1)) output from output terminals of previous stages as start signals (START1 to START(n-1)).

For example, a first scan signal SC1 output from the output terminal of the first gate driving integrated circuit GDIC1 of the first stage STG1, may be applied to a first subpixel line SPL1 and a start signal input terminal of a second gate driving integrated circuit GDIC2 of the second stage STG2.

Accordingly, the first gate driving integrated circuit GDIC1 of the first stage STG1 may use the gate start signal GVST as a start signal, but the second gate driving integrated circuit GDIC2 of the second stage STG2 to the nth gate driving integrated circuit GDICn of the nth stage STGn may use scan signals (SC1 to SC(n-1)) output from the output terminals of the gate driving integrated circuits (GDIC1 to GDIC(n-1)) located in previous stages as start signals (START1 to START(n-1)), respectively.

It should be noted that in FIG. 5, the first scan signal SC1 output from the output terminal of the first gate driving integrated circuit GDIC1 is expressed as the first start signal START1 to show that the first scan signal SC1 generated in the first stage STG1 is used as a start signal of the next stage.

This configuration of using the scan signal of the previous stage as the start signal of the next stage in the stages connected in the cascade may be applied equally to all stages (STG1 to STGn), as can be seen from the relationship between the (n-1)th stage STG(n-1) and the nth stage STGn in FIG. 5.

It should be noted that FIG. 5 illustrates an example where one scan signal is output from one stage (one gate driver integrated circuit), but two scan signals or four scan signals may be output from one stage (one gate driver integrated circuit) depending on the configuration of each or one or more of the gate driver integrated circuits.

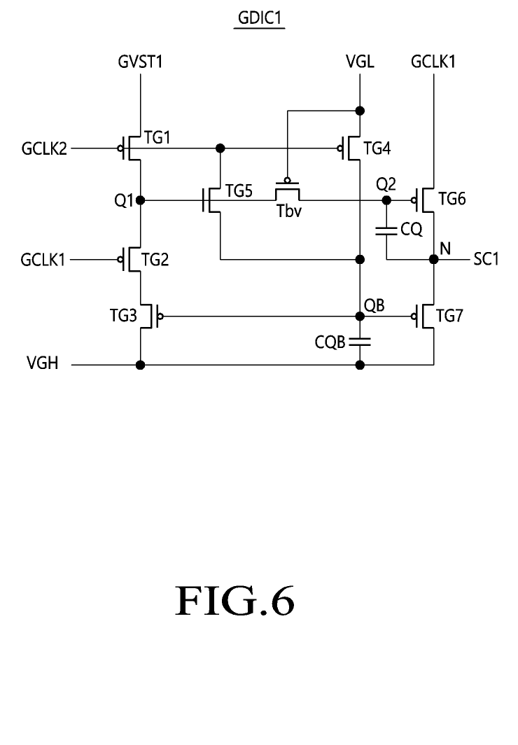

FIG. 6 illustrates an example gate driving integrated circuit configured to output at least one scan signal in the display device 100 according to aspects of the present disclosure.

It should be noted here that FIG. 6 illustrates, as an example, a first gate driving integrated circuit GDIC1 that outputs a first scan signal SC1.

Referring to FIG. 6, in one or more example embodiments, the first gate driving integrated circuit GDIC1 may include first to seventh transistors (TG1 to TG7), an auxiliary transistor Tbv, a first capacitor CQ, and a second capacitor CQB.

The first transistor TG1 may be switched by a second gate clock signal GCLK2 and supply a gate start signal GVST1 to a Q1 node Q1.

The second transistor TG2 may be switched by a first gate clock signal GCLK1, and one of the source electrode and the drain electrode of second transistor TG2 may be electrically connected to the Q1 node Q1.

The third transistor TG3 may be switched by a voltage of a QB node QB and supply a gate high voltage VGH to one of the source electrode and the drain electrode of the second transistor TG2.

The fourth transistor TG4 may be switched by the second gate clock signal GCLK2 and supply a gate low voltage VGL to the QB node QB.

The fifth transistor TG5 may be switched by a voltage of the Q1 node Q1 and supply the second gate clock signal GCLK2 to the QB node QB.

In these configurations, when the fifth transistor TG5 is implemented as an oxide transistor, the gate driving integrated circuit can provide an effect or advantage of reducing image artifacts such as flicker by preventing current leakage.

In this implementation, the fifth transistor TG5 may have a double-gate structure to reduce or eliminate leakage current due to charge injection while display driving is performed.

The sixth transistor TG6 may be an output buffer, operation of which may be controlled by a voltage of a Q2 node Q2. The sixth transistor TG6 may be activated when the Q2 node Q2 is at the gate low voltage VGL and output the first gate clock signal GCLK1 to an output node N.

The seventh transistor TG7 may be an output buffer, operation of which may be controlled by a voltage of the QB node QB. The seventh transistor TG7 may be activated when the QB node QB is at the gate low voltage VGL and output a scan signal of the gate high voltage VGH to the output node N.

The auxiliary transistor Tbv may remain in a turn-on state by the gate low voltage VGL. The auxiliary transistor Tbv may cause the voltages of the Q1 node Q1 and the Q2 node Q2 to be substantially equal.

The first capacitor CQ may be connected between the Q2 node Q2 and the output node N and be configured to store a voltage of the Q2 node Q2.

The second capacitor CQB may be connected between the QB node QB and an input terminal of the gate high voltage VGH, and be configured to store a voltage of the QB node QB.

In these configurations, in an example where a transistor with a double gate structure is employed, when an upper interlayer insulating layer has a small thickness, the transistor with the double gate structure may suffer from a seam defect occurring in a boundary area of an upper gate electrode, and the degradation of switching characteristics as a channel width of an active layer is reduced.

To address these issues, in one or more aspects, a transistor with a double gate structure and a display device 100 including the transistor can provide an advantage of improving the switching characteristics thereof by designing an active layer to have an increased channel width.

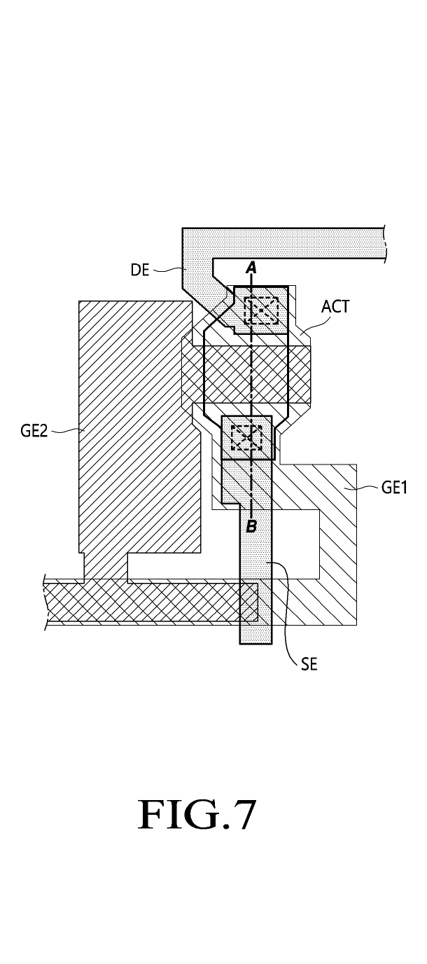

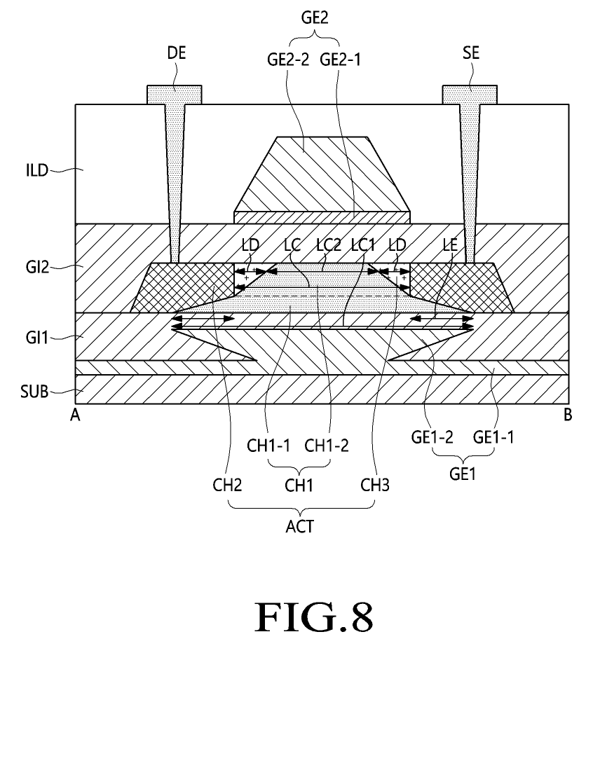

FIG. 7 is an example plan view of a double gate transistor included in the display device 100 according to embodiments of the present disclosure. FIG. 8 is an example cross-sectional view of the double gate transistor taken along line A-B in FIG. 7 according to embodiments of the present disclosure.

Referring to FIGS. 7 and 8, in one or more example embodiments, at least one subpixel SP or the gate driving circuit 120 included in the display device 100 may include a transistor with double gates (which may be referred to as a double gate transistor) implemented as an oxide transistor.

The double gate transistor may include a first gate electrode GE1 including a first gate material disposed on a substrate SUB.

In one or more embodiments, a buffer layer may be disposed between the substrate SUB and the first gate electrode GE1.

In one or more embodiments, the first gate material may be an opaque conductive material having low resistance, such as aluminum (Al), aluminum alloy, tungsten (W), copper (Cu), nickel (Ni), chromium (Cr), molybdenum (Mo), titanium (Ti), platinum (Pt), tantalum (Ta), and/or the like. In one or more aspects, the first gate material may have a multilayer structure in which a transparent conductive material such as indium-tin oxide (ITO), indium-zinc oxide (IZO), or the like and an opaque conductive material are stacked.

The first gate electrode GE1 may be a lower gate electrode (which may be also referred to as a bottom gate electrode) of the double gate transistor.

The first gate electrode GE1 may include a first-first gate electrode GE1-1 and a first-second gate electrode GE1-2 disposed on the first-first gate electrode GE1-1. The first-first gate electrode GE1-1 may be referred to as a first lower gate electrode, and the first-second gate electrode GE1-2 may be referred to as a second lower gate electrode.

The foregoing expression may be differently described such that the first gate electrode GE1 includes a first-first gate region GE1-1 and a first-second gate region GE1-2. In this case, among regions of the first gate electrode GE1, the first-second gate region GE1-2 may be referred to as an upper region of an inverse taper shape, and the first-first gate region GE1-1 may be referred to as a lower region of the first-second gate region GE1-2.

The first-first gate region GE1-1 and the first-second gate region GE1-2 may include the same material or include different materials.

A width of first-first gate region GE1-1 may be greater than that of an active layer ACT.

The first-second gate region GE1-2 may have a shape tapered at a certain angle toward the substrate SUB (hereinafter, which may be referred to as an inverse taper shape), and therefore, a lower portion of the first-second gate region GE1-2 may have a width less than a width of the active layer ACT disposed over the first-second gate region GE1-2.

In this implementation, a width of an upper portion of the first-second gate region GE1-2 may correspond to a first channel width LC1 at a lower portion of the active layer ACT.

The active layer ACT included in the double gate transistor may include an oxide semiconductor. A transistor including the active layer ACT including an oxide semiconductor may be referred to as an oxide transistor. For example, the oxide semiconductor may be an N-type oxide semiconductor such as IGZO, IZO, or ITZO, or a P-type oxide semiconductor such as CuOx, SnOx, or NiOx.

The first channel width LC1 of the active layer ACT may be a width of an area resulting from the adding of an extended channel width LE expanded by the first-second gate region GE1-2 during the process of doping an impurity to an initial channel width LC of the active layer ACT.

For example, the first channel width LC1 of the lower portion of the active layer ACT may have a value of (LC + 2LE) that results from the summing of the initial channel width LC and extended channel widths (2 × LE) on both sides.

For example, a second channel width LC2 of an upper portion of the active layer ACT may have a value of (LC -2LD) that results from the subtracting of extended channel widths (2 × LD) reduced by diffusion regions CH3 on both sides from the initial channel width LC.

Therefore, when a width of an upper portion of the first gate electrode GE1 is formed to be greater than a width of an upper portion of a second gate electrode GE2, the first channel width LC1 of the lower portion of the active layer ACT may be formed to be greater than the second channel width LC2 of the upper portion of the active layer ACT.

In this case, respective tapered angles of the first gate electrode GE1 and the second gate electrode GE2 may be determined to be proportional to a capacitance by the active layer ACT.

For example, when a ratio of a first capacitance formed between the active layer ACT and the first gate electrode GE1 and a second capacitance formed between the active layer ACT and the second gate electrode GE2 is 1:2, a tapered angle of the first gate electrode GE1 and a tapered angle of the second gate electrode GE2 may have a value of 1:2.

A first gate insulating layer GI1 may be disposed such that it covers the first gate electrode GE1.

The active layer ACT included in the double gate transistor may be disposed on the first gate insulating layer GI1.

The active layer ACT may include a channel region CH1, conductive semiconductor regions CH2, and diffusion regions CH3.

The channel region CH1 may be a region where a channel is formed in the active layer ACT when a gate voltage of a turn-on level is applied to the first gate electrode GE1 and the second gate electrode GE2.

The conductive semiconductor regions CH2 may be conductivity-enabled regions formed through impurity doping to which a source electrode SE and a drain electrode DE are electrically connected, respectively. The diffusion regions CH3 may be regions where electrons or holes in the channel region CH1 diffuse towards the conductive semiconductor regions CH2.

In these configurations, to provide the double gate transistor with excellent switching characteristics, it can be required that the active layer CAT of the double gate transistor has a great channel width.

In one or more aspects, as shown in FIG. 8, as the first gate electrode GE1 (which is a lower gate electrode) of the double gate transistor of the present disclosure is formed in an inverse taper shape, the double gate transistor and the display device 100 including the double gate transistor can provide advantages of increasing the channel width of the active layer ACT and improving the switching characteristics.

A second gate insulating layer GI2 may be disposed such that it covers the active layer ACT.

The second gate electrode GE2 including a second gate material may be disposed on the second gate insulating layer GI2.

The second gate electrode GE2 may be an upper gate electrode (which may be also referred to as a top gate electrode) of the double gate transistor.

The second gate electrode GE2 may include a second-first gate electrode GE2-1 and a second-second gate electrode GE2-2 disposed on the second-first gate electrode GE2-1.

The second-first gate electrode GE2-1 may be referred to as a first upper gate electrode, and the second-second gate electrode GE2-2 may be referred to as a second upper gate electrode.

The foregoing expression may be differently described such that the second gate electrode GE2 includes a second-first gate region GE2-1 and a second-second gate region GE2-2.

The second-first gate region GE2-1 and the second-second gate region GE2-2 may include the same material or include different materials.

The second gate electrode GE2 may have a shape tapered at a certain angle in a direction opposite to the substrate SUB (hereinafter, which may be referred to as a taper shape) to prevent a seam defect from occurring in a boundary area.

In this configuration, the second-first gate region GE2-1 may be formed in a rectangular shape with a thickness smaller than the second-second gate region GE2-2, and the second-second gate region GE2-2 may be formed in the taper shape.

According to these configurations, the channel region CH1 may have different doped impurity concentrations in upper and lower portions thereof due to the first gate electrode GE1 with the inverse taper shape and the second gate electrode GE2 with the taper shape, and thereby, the first channel width LC1 in the lower portion and the second channel width LC2 in the upper portion may become different from each other.

Accordingly, the channel region CH1 may include a first channel region CH1-1 corresponding to the shape of the first gate electrode GE1 and a second channel region CH1-2 corresponding to the shape of the second gate electrode GE2. The first channel region CH1-1 may have a trapezoidal shape in which the first channel width LC1 of the lower portion of the first channel region CH1-1 corresponds to the width of the upper portion of the first gate electrode GE1.

In one or more embodiments, the second channel region CH1-2 may have a trapezoidal shape in which the second channel width LC2 of the upper portion of the second channel region CH1-2 corresponds to the width of the upper portion of the second gate electrode GE2.

An interlayer insulating layer ILD may be disposed on the second gate electrode GE2.

A contact hole may be formed by the etching of respective portions of the interlayer insulating layer ILD and the second gate insulating layer GI2 to expose a portion of the active layer ACT, and a source electrode SE and a drain electrode DE that contact the active layer ACT may be formed through the contact hole.

According to the configurations discussed above, the double gate transistor of the present disclosure can provide effects or advantages of improving the switching characteristics by increasing the first channel width LC1 of the active layer ACT by the first gate electrode GE1 having the inverse taper shape, and preventing a seam defect in a boundary area by the second gate electrode GE2 having the taper shape.

In one or more embodiments, the double gate transistor including the first gate electrode GE1 having the inverse taper shape and the second gate electrode GE2 having the taper shape may be configured in a switching transistor including an oxide semiconductor.

In one or more embodiments, a driving transistor including an oxide semiconductor may include the first gate electrode GE1 having a rectangle shape and the second gate electrode GE2 having the taper shape.

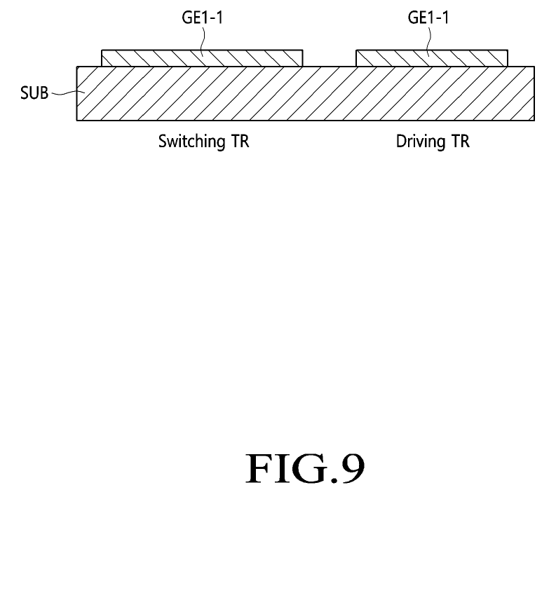

FIGS. 9 to 13 illustrate an example process of manufacturing a double gate transistor included in the display device 100 according to embodiments of the present disclosure.

In one or more example embodiments, at least one switching transistor among a plurality of transistors included in the display device 100 may include a first gate electrode GE1 having an inverse taper shape and a second gate electrode GE2 having a taper shape. In one or more example embodiments, at least one driving transistor among the plurality of transistors may include a first gate electrode GE1 having a rectangle shape and a second gate electrode GE2 having a taper shape.

Referring to FIG. 9, a first-first gate electrode GE1-1 including a first gate material may be formed in an area where the switching transistor is to be disposed and an area where the driving transistor is to be disposed on a substrate SUB.

In one or more embodiments, a buffer layer may be additionally formed on the substrate SUB, and in this implementation, the first-first gate electrode GE1-1 may be located on the buffer layer.

The first-first gate electrode GE1-1 in the area where the switching transistor is to be disposed and the first-first gate electrode GE1-1 in the area where the driving transistor is to be disposed may have different widths from each other.

In one or more embodiments, the first gate material may be an opaque conductive material having low resistance, such as aluminum (Al), aluminum alloy, tungsten (W), copper (Cu), nickel (Ni), chromium (Cr), molybdenum (Mo), titanium (Ti), platinum (Pt), tantalum (Ta), and/or the like.

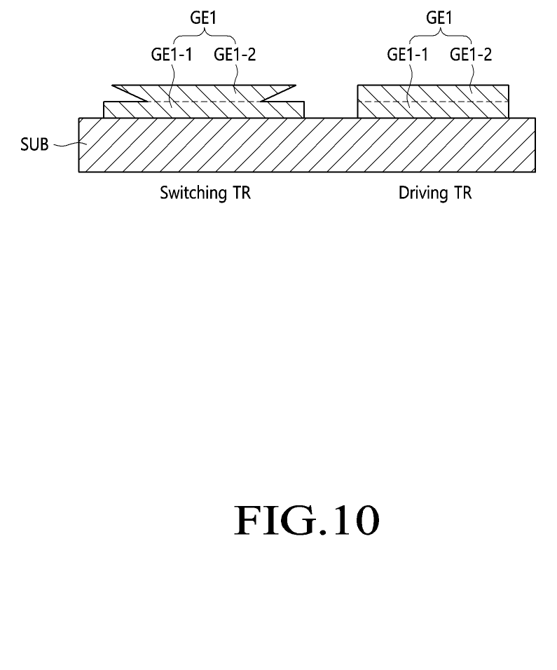

Referring to FIG. 10, a first-second gate electrode GE1-2 of the first gate material may be formed on the first-first gate electrode GE1-1.

In this implementation, the first-second gate electrode GE1-2 disposed in the area of the switching transistor may have the inverse taper shape, and the first-second gate electrode GE1-2 disposed in the area of the driving transistor may have the rectangle shape.

The first-first gate electrode GE1-1 and the first-second gate electrode GE1-2 may include the same gate material.

The first-first gate electrode GE1-1 and the first-second gate electrode GE1-2 may be included in a first gate electrode GE1 and may be a lower gate electrode of the switching transistor and a lower gate electrode of the driving transistor.

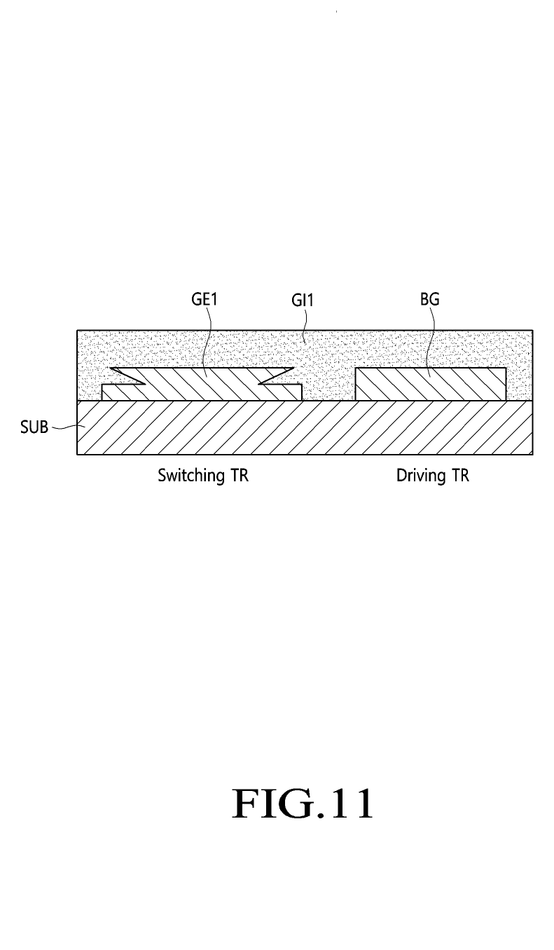

Referring to FIG. 11, a first gate insulating layer GI1 may be formed such that it covers the first gate electrode GE1.

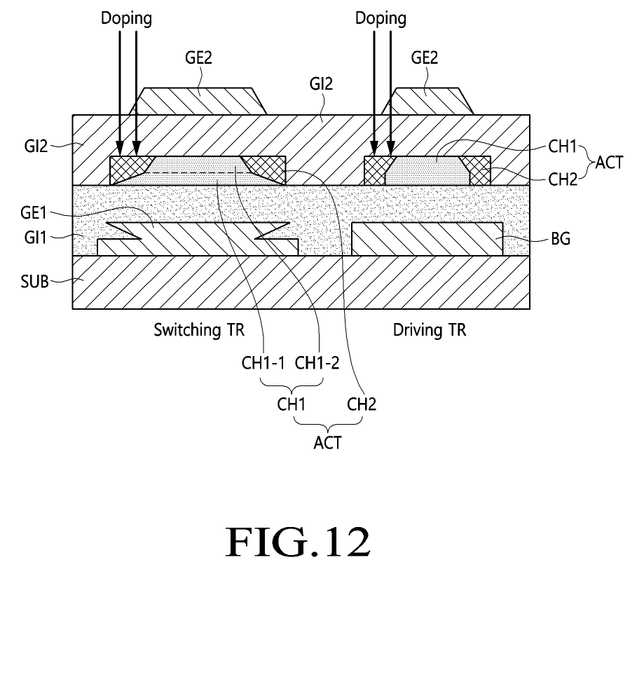

Referring to FIG. 12, an active layer ACT may be formed on the first gate insulating layer GI1, and a second gate insulating layer GI2 may be formed such that the second gate insulating layer GI2 covers the active layer ACT.

The active layer ACT may be a semiconductor layer including hydrogenated amorphous silicon, or the like.

A second gate electrode GE2 of a second gate material, which may be an upper gate electrode, may be formed on the second gate insulating layer GI2. The second gate material may be the same as the first gate material.

The second gate electrode GE2 in the area of the switching transistor may be the upper gate electrode of the switching transistor, and the second gate electrode GE2 in the area of the driving transistor may be the upper gate electrode of the driving transistor.

The second gate electrode GE2 may have a width less than the active layer ACT.

In a state where the second gate electrode GE2 is formed, an impurity may be doped into the active layer ACT, and thereby, a channel region CH1 and conductive semiconductor regions CH2 may be formed.

In one or more embodiments, during the process of doping the impurity into the active layer ACT, a photoresist may be applied to cover the second gate electrode GE2.

The switching transistor may be formed such that a lower channel region of the active layer ACT is formed in a taper shape corresponding to the structure of the first gate electrode GE1 by the first gate electrode GE1 having the inverse taper shape.

In contrast, the driving transistor may be formed such that a channel region of the active layer ACT is formed in the rectangle shape or a trapezoidal shape by the first gate electrode GE1 having the rectangle shape.

In one or more aspects, the active layer ACT may include diffusion regions CH3 between the channel region CH1 and the conductive semiconductor regions CH2.

The channel region CH1 may be a region forming a semiconductor surface through impurity doping, and the conductive semiconductor regions CH2 may be conductivity-enabled regions formed through impurity doping to which a source electrode SE and a drain electrode DE are electrically connected, respectively. The diffusion regions CH3 may be regions where electrons or holes in the channel region CH1 diffuse towards the conductive semiconductor regions CH2.

It should be understood here that when an amount of impurity doped into the active layer ACT is increased, a seam defect in a boundary area may be reduced, but the conductive semiconductor regions CH2 may increase and the channel region CH1 may decreases, this resulting in the reliability characteristics of the transistor being degraded.

According to the configurations described above, the double gate transistor can provide an advantage of increasing an effective channel width formed at the lower portion of the active layer ACT by the structure in which the first gate electrode GE1 at the lower portion is formed in an inverse taper shape.

For example, the first gate electrode GE1 may be formed to have a width greater than the second gate electrode GE2. According to this implementation, a first channel region CH1-1 of the active layer ACT formed by the first gate electrode GE1 may be formed wider than a second channel region CH1-2 of the active layer ACT formed by the second gate electrode GE2.

As a result, the first channel region CH1-1 may be formed to have a width greater than the second gate electrode GE2. In contrast, the second channel region CH1-2 may be formed to have a width less than the first gate electrode GE1.

As a result, a phenomenon in which a threshold voltage of the switching transistor is shifted can be reduced, and the mobility characteristics can be improved.

In one or more embodiments, the diffusion regions CH3 of the active layer ACT of the double gate transistor may be reduced by performing the process of doping an impurity into the active layer ACT two or more times.

For example, the reduction of the diffusion regions CH3 of the active layer ACT may be performed through the process of increasing the first channel width LC1 in the lower portion of the active layer ACT through first impurity doping after a photoresist is formed on the second gate electrode GE2, and thereafter, increasing the conductive semiconductor regions CH2 in an upper portion of the active layer ACT through second impurity doping after the photoresist is removed.

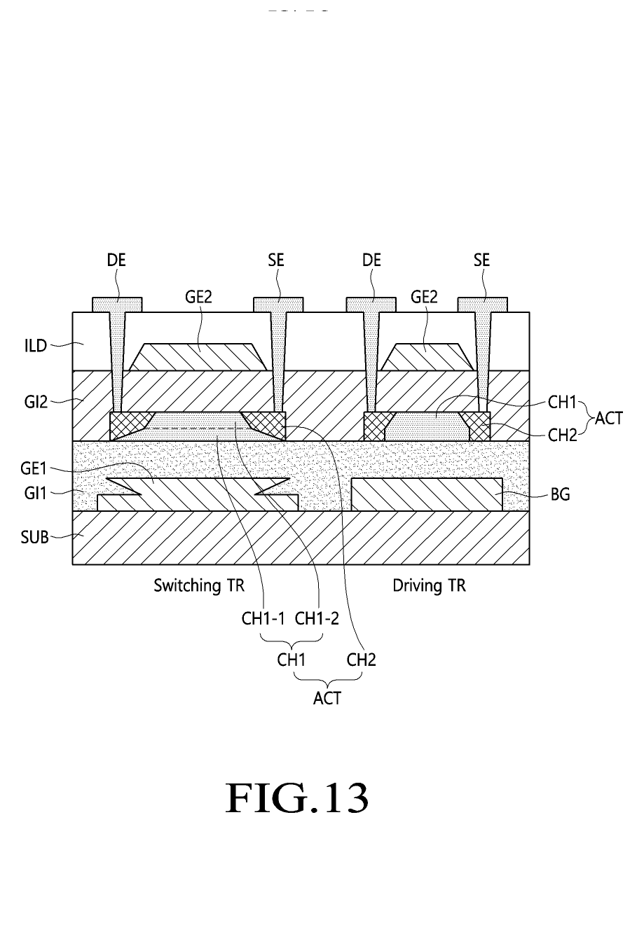

Referring to FIG. 13, an interlayer insulating layer ILD may be disposed on the second gate electrode GE2.

Contact holes may be formed by the etching of respective portions of the interlayer insulating layer ILD and the second gate insulating layer GI2 to expose portions of the active layer ACT, and a source electrode SE and a drain electrode DE that contact the active layer ACT may be formed through the contact holes.

In one or more embodiments, a corresponding first gate electrode of at least one double gate transistor may have a single layer of one material or a stack structure of two or more materials.

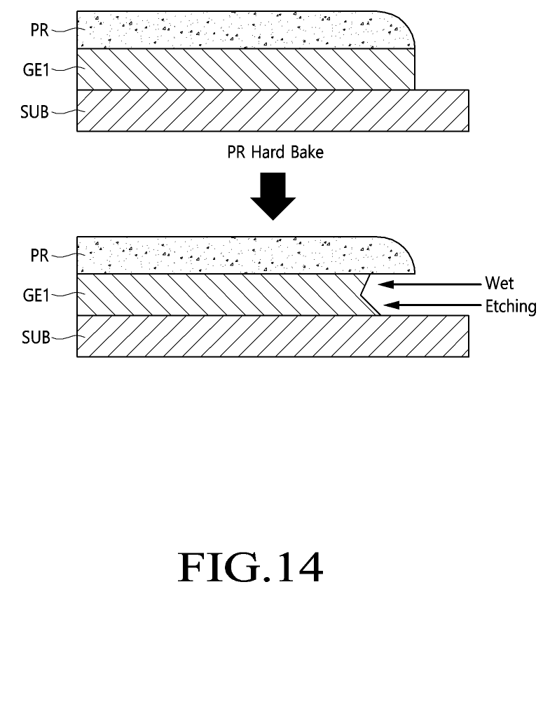

FIG. 14 illustrates an example process of forming a first gate electrode of a single layer structure in an inverse taper shape in a double gate transistor according to aspects of the present disclosure.

Referring to FIG. 14, in one or more example embodiments, a corresponding first gate electrode GE1 of at least one double gate transistor may be formed in a single layer of one gate material on a substrate SUB.

For example, the first gate electrode GE1 may be formed in a single layer of molybdenum (Mo).

In this example, after a photoresist PR is applied on the first gate electrode GE1, a process for improving adhesion between the first gate electrode GE1 and the photoresist PR may be performed through a hard bake process.

After the first gate electrode GE1 and the photoresist PR are bonded, a side surface of the first gate electrode GE1 may be etched through a wet etching process. As in this implementation, a central portion in the side surface of the first gate electrode GE1 may be etched most by the wet etching process performed after the first gate electrode GE1 and the photoresist PR are bonded. In one or more aspects, the first gate electrode GE1 may include an upper first-second gate region with an inverse taper shape and a lower first-first gate region with a taper shape.

In the double gate transistor according to the configurations discussed above, a channel width in a lower portion of the active layer ACT formed on the first gate electrode GE1 can be increased during an impurity doping process by the first-second gate region with the inverse taper shape.

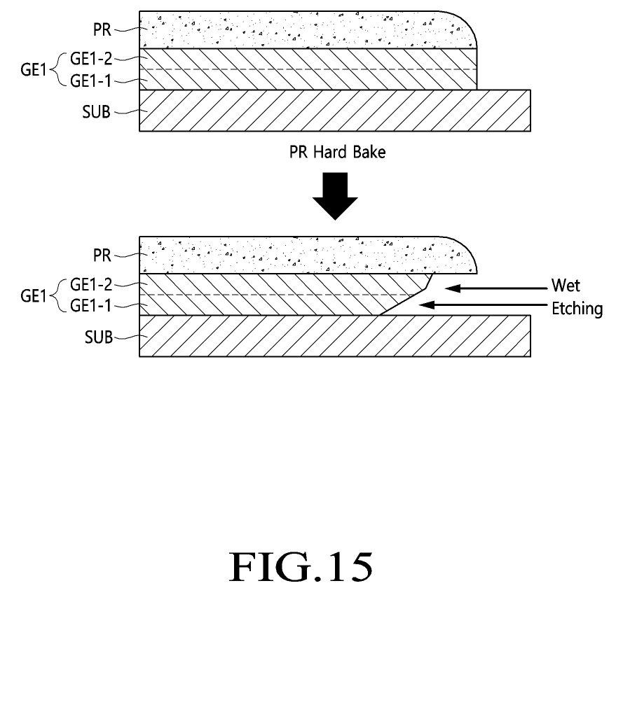

FIG. 15 illustrates an example process of forming a first gate electrode of a double layer structure in an inverse taper shape in a double gate transistor according to aspects of the present disclosure.

Referring to FIG. 15, in one or more example embodiments, a corresponding first gate electrode GE1 of at least one double gate transistor may be formed in double layers of different gate materials on a substrate SUB.

For example, a first gate electrode GE1 may include a first-first gate electrode GE1-1 including copper (Cu) and a first-second gate electrode GE1-2 including titanium (Ti) or a molybdenum-titanium alloy (MoTi).

After a photoresist PR is applied on the first gate electrode GE1 in which the first-first gate electrode GE1-1 and the first-second gate electrode GE1-2 are stacked, a process for improving adhesion between the first gate electrode GE1 and the photoresist PR may be performed through a hard bake process.

After the first gate electrode GE1 and the photoresist PR are bonded, a side surface of the first gate electrode GE1 may be etched through a wet etching process. In this implementation, a degree to which the etching is performed may vary depending on materials of the first-first gate electrode GE1-1 and the first-second gate electrode GE1-2.

For example, an etching degree of the first-first gate electrode GE1-1 including copper (Cu) may be greater than an etching degree of the first-second gate electrode GE1-2 including a molybdenum-titanium alloy (MoTi).

In this example, the first gate electrode GE1 may be formed such that a width of the first-first gate electrode GE1-1 is greater than a width of the first-second gate electrode GE1-2 with respect to a surface of the first gate insulating layer GL1.

According to the configurations discussed above, the double gate transistor can provide an increased channel width in a lower portion of the active layer ACT formed on the first gate electrode GE1 during an impurity doping process by the first gate electrode GE1 with an inverse taper shape.

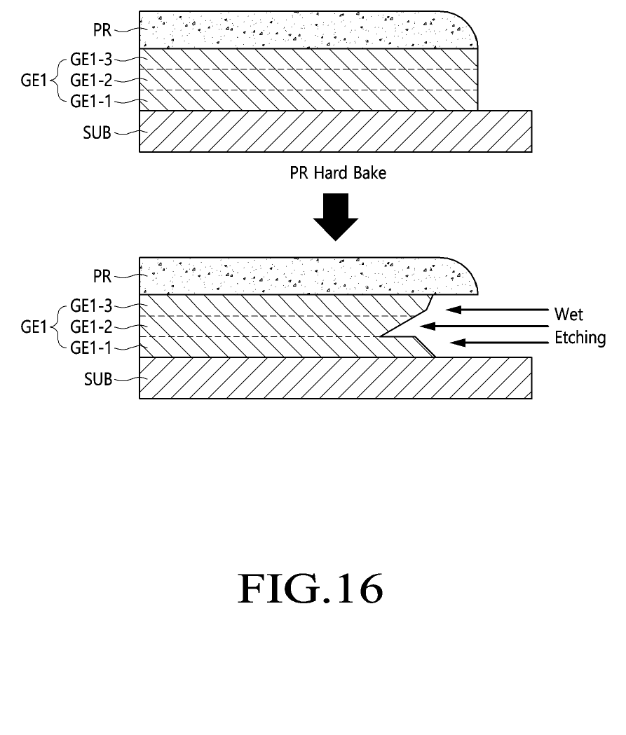

FIG. 16 illustrates an example process of forming a first gate electrode of a triple layer structure in an inverse taper shape in a double gate transistor according to aspects of the present disclosure.

Referring to FIG. 16, in one or more example embodiments, a first gate electrode GE1 included in a double gate transistor may be configured in a triple layer structure in which a first-first gate electrode GE1-1, a first-second gate electrode GE1-2, and a first-third gate electrode GE1-3 are stacked on a substrate SUB.

For example, the first gate electrode GE1 may include the first-first gate electrode GE1-1 including titanium (Ti) or a molybdenum-titanium alloy (MoTi), the first-second gate electrode GE1-2 including aluminum (Al) or copper (Cu), and the first-third gate electrode GE1-3 including titanium (Ti) or a molybdenum-titanium alloy (MoTi).

After a photoresist PR is applied on the first gate electrode GE1 in which the first-first gate electrode GE1-1, the first-second gate electrode GE1-2, and the first-third gate electrode GE1-3 are stacked, a process for improving adhesion between the first gate electrode GE1 and the photoresist PR may be performed through a hard bake process.

After the first gate electrode GE1 and the photoresist PR are bonded, a side surface of the first gate electrode GE1 may be etched through a wet etching process. In this implementation, a degree to which the etching is performed may vary depending on materials of the first-first gate electrode GE1-1, the first-second gate electrode GE1-2, and the first-third gate electrode GE1-3.

For example, an etching degree of the first-second gate electrode GE1-2 including aluminum (Al) or copper (Cu) may be greater than respective etching degrees of the first-first gate electrode GE1-1 and the first-third gate electrode GE1-3 including titanium (Ti) or a molybdenum-titanium alloy (MoTi).

In this example, the first gate electrode GE1 may be formed such that a width of the first-third gate electrode GE1-3 disposed on the first-second gate electrode GE1-2 is greater than that of the first-second gate electrode GE1-2.

According to the configurations discussed above, the double gate transistor can provide an increased channel width in a lower portion of the active layer ACT formed on the first gate electrode GE1 during an impurity doping process by the first gate electrode GE1 with an inverse taper shape.

In one or more aspects, a double gate transistor may include a process of performing impurity doping to the active layer ACT once, or include a process of performing impurity doping to the active layer ACT twice or more with different impurity doping concentrations or different impurity doping time to form the active layer ACT into multiple regions with different mobilities.

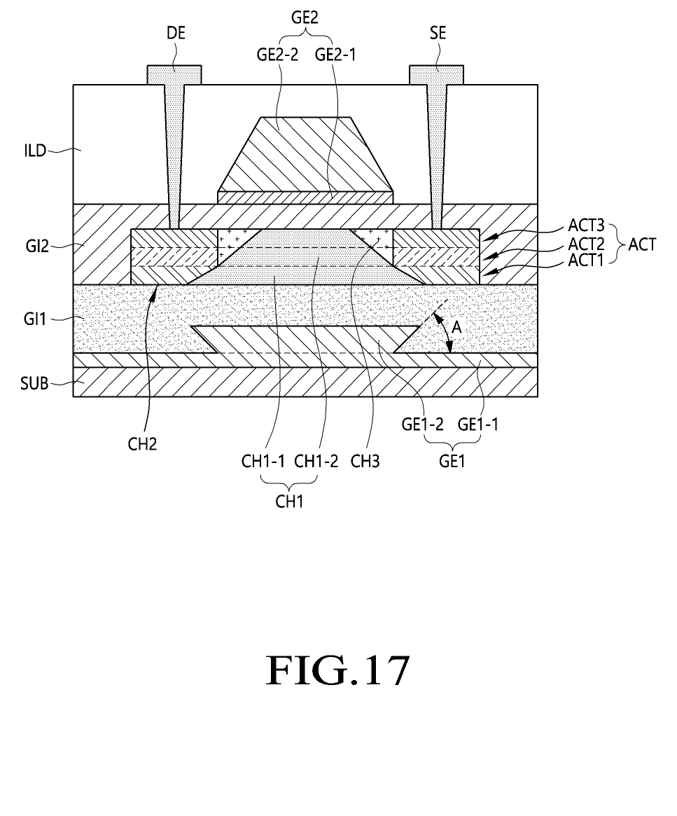

FIG. 17 illustrates an example structure of a double gate transistor including an active layer of a triple layer structure according to aspects of the present disclosure.

Referring to FIG. 17, in one or more example embodiments, a double gate transistor may include a first gate electrode GE1 in which a first-first gate electrode GE1-1 and a first-second gate electrode GE1-2 are sequentially stacked on a substrate SUB. The first-first gate electrode GE1-1 may be referred to as a first-first gate region, and the first-second gate electrode GE1-2 may be referred to as a first-second gate region.

A first gate insulating layer GI1 may be disposed such that it covers the first gate electrode GE1.

An active layer ACT included in the double gate transistor may be disposed on the first gate insulating layer GI1.

In this configuration, the active layer ACT may be configured in the form of triple regions (or triple layers) with different mobilities by applying different impurity doping concentrations or different impurity doping time to the active layer ACT.

For example, the active layer ACT can include a first active region ACT1 having a first mobility, a second active region ACT2 having a second mobility, and a third active region ACT3 having a third mobility.

In this configuration, the second mobility of the second active region ACT2 located between the first active region ACT1 and the third active region ACT3 may be formed to be greater than each of the first mobility of the first active region ACT1 and the third mobility of the third active region ACT3.

In this case, considering that a current path of the double gate transistor may be mostly formed in the second active region ACT2 having greater mobility, to increase a channel width for the second active region ACT2, the double gate transistor may be formed such that an inclined angle A of the first gate electrode GE1 having an inverse taper shape (i.e., the first-second gate electrode GE1-2 in FIG. 17) to the first-first gate electrode GE1-1 has a larger value.

The inclined angle A of the first gate electrode GE1 having the inverse taper shape may vary depending on a difference in the mobilities of layers or regions of the active layer ACT.

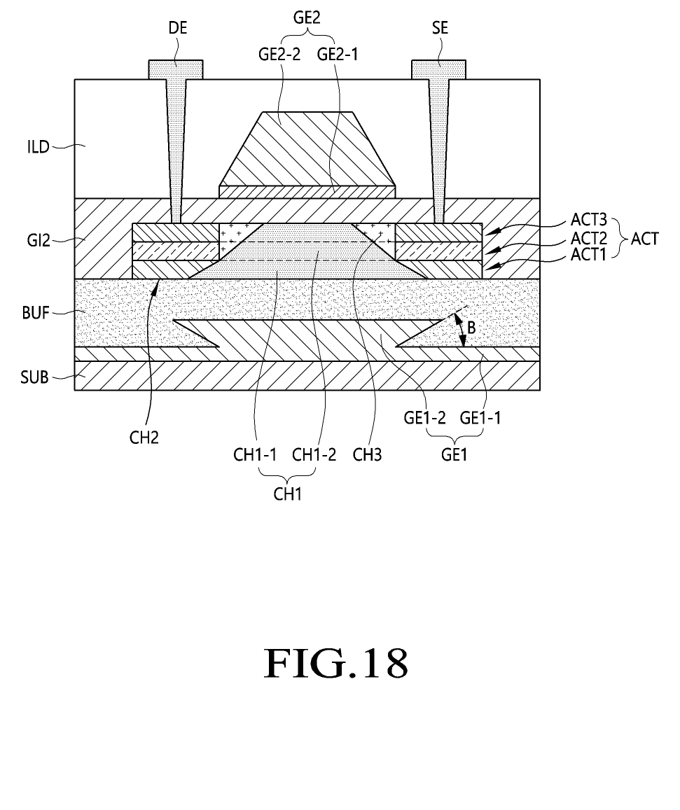

FIG. 18 illustrates another example structure of a double gate transistor including an active layer of a triple layer structure according to aspects of the present disclosure.

Referring to FIG. 18, in one or more example embodiments, a double gate transistor may include a first gate electrode GE1 in which a first-first gate electrode GE1-1 and a first-second gate electrode GE1-2 are sequentially stacked on a substrate SUB. The first-first gate electrode GE1-1 may be referred to as a first-first gate region, and the first-second gate electrode GE1-2 may be referred to as a first-second gate region.

A first gate insulating layer GI1 may be disposed such that it covers the first gate electrode GE1.

An active layer ACT included in the double gate transistor may be disposed on the first gate insulating layer GI1.

The active layer ACT may have a channel region CH1, conductive semiconductor regions CH2, and diffusion regions CH3 by impurity doping.

In this configuration, the active layer ACT may be configured in the form of triple regions (or triple layers) with different mobilities by applying different impurity doping concentrations or different impurity doping time to the active layer ACT.

For example, the active layer ACT can include a first active region ACT1 having a first mobility, a second active region ACT2 having a second mobility, and a third active region ACT3 having a third mobility.

In this configuration, the third mobility of the third active region ACT3 located furthest away from the substrate SUB may be formed to be greater than each of the first mobility of the first active region ACT1 and the second mobility of the second active region ACT2.

In this case, a current path of the double gate transistor may be mostly formed in the third active region ACT2 having greater mobility. Accordingly, to increase a channel width for the third active region ACT3, the double gate transistor may be formed such that an inclined angle B of the first gate electrode GE1 having an inverse taper shape (i.e., a first-second gate electrode GE1-2 in FIG. 18) to a first-first gate electrode GE1-1 has a smaller value, leading a width of the first gate electrode GE1 to be increased.

According to the configurations discussed above, the double gate transistor of the present disclosure can provide effects or advantages of improving the switching characteristics of switching transistors by increasing a channel width of the active layer ACT through impurity doping by the first gate electrode GE1 having an inverse taper shape, and preventing a seam defect in a boundary area by the second gate electrode GE2 having a taper shape.

The example embodiments described above will be briefly described as follows.

According to the one or more example embodiments described herein, a double gate transistor can be provided that includes a first gate electrode disposed on a first gate insulating layer and having an inverse taper shape, a buffer layer disposed to cover the first gate electrode, an active layer disposed on the buffer layer, a second gate insulating layer disposed to cover the active layer, and a second gate electrode disposed on the second gate insulating layer and having a taper shape.

In one or more embodiments, the first gate electrode may include a first-first gate region disposed on the first gate insulating layer and having a rectangular shape; and a first-second gate region disposed on the first-first gate region and having an inverse taper shape.

In one or more aspects, a width of the first-first gate region may be greater than a width of the second gate electrode.

In one or more embodiments, the first gate electrode may include a first-first gate region disposed on the first gate insulating layer and having a taper shape, and a first-second gate region disposed on the first-first gate region and having an inverse taper shape.

In one or more embodiments, the first gate electrode may include a first-first gate region disposed on the first gate insulating layer and having an inverse taper shape, and a first-second gate region disposed on the first-first gate region and having an inverse taper shape. In this implementation, a width of the first-second gate region may be greater than a width of the first-first gate region.

In one or more embodiments, the first-first gate region may include copper, and the first-second gate region may include titanium or a molybdenum-titanium alloy.

In one or more embodiments, the first gate electrode may include a first-first gate region disposed on the first gate insulating layer and having a taper shape, a first-second gate region disposed on first-first gate region and having an inverse taper shape, and a first-third gate region disposed on first-second gate region and having an inverse taper shape. In this implementation, a width of the first-third gate region may be greater than a width of the first-second gate region.

In one or more embodiments, the first-first gate region may include titanium or a molybdenum-titanium alloy, the first-second gate region may include copper, and the first-third gate region may include titanium or a molybdenum-titanium alloy.

In one or more embodiments, the active layer may include a channel region formed in a central region thereof, conductive semiconductor regions located on both sides of the channel region and doped with an impurity, and diffusion regions formed between the channel region and each of the conductive semiconductor regions. In this implementation, the conductive semiconductor regions may include a plurality of regions with different mobilities formed by performing impurity doping twice or more.

In one or more embodiments, wherein the conductive semiconductor regions may include a first conductive semiconductor region disposed on the buffer layer and having a first mobility, a second conductive semiconductor region disposed on the first conductive semiconductor region and having a second mobility, and a third conductive semiconductor region disposed on the second conductive semiconductor region and having a third mobility.

In one or more embodiments, the second mobility may be greater than the first mobility and the third mobility.

In one or more embodiments, a width of the first gate electrode may be the same as that of the channel region.

In one or more embodiments, the third mobility may be greater than the first mobility and the second mobility.

In one or more embodiments, a width of the first gate electrode may be greater than that of the channel region.

In one or more embodiments, a ratio of a tapered angle of the first gate electrode and a tapered angle of the second gate electrode may be proportional to a ratio of a first capacitance formed between the active layer and the first gate electrode and a second capacitance formed between the active layer and the second gate electrode.

According to the one or more example embodiments described herein, a display device can be provided that includes a display panel in which a plurality of subpixels are disposed, a gate driving circuit configured to supply at least one gate signal to the display panel, a data driving circuit configured to supply at least one data signal to the display panel, a timing controller for controlling the gate driving circuit and the data driving circuit, at least one of the plurality of subpixels including a double gate transistor including a first gate electrode disposed on a first gate insulating layer having an inverse taper shape, a buffer layer disposed to cover the first gate electrode, an active layer disposed on the buffer layer, a second gate insulating layer disposed to cover the active layer, and a second gate electrode disposed on the second gate insulating layer and having a taper shape.

In one or more embodiments, the at least one subpixel may include a light emitting element, a driving transistor for providing current to the light emitting element, a first transistor connected between a gate node and a drain node of the driving transistor, a second transistor connected between a data line and a source node of the driving transistor, a third transistor connected between a driving voltage line and the source node of the driving transistor, a fourth transistor connected between the drain node of the driving transistor and an anode electrode of the light emitting element, a fifth transistor connected between the gate node of the driving transistor and an initialization voltage line, a sixth transistor connected between an anode reset voltage line and the anode electrode of the light-emitting element, and a storage capacitor connected between the driving voltage line and the fifth transistor. In this implementation, the first transistor or the fifth transistor may be configured as the double gate transistor.

According to the one or more example embodiments described herein, a display device can be provided that includes a display panel in which a plurality of subpixels are disposed, a gate driving circuit configured to supply at least one gate signal to the display panel, a data driving circuit configured to supply at least one data signal to the display panel, a timing controller for controlling the gate driving circuit and the data driving circuit, the gate driving circuit including a double gate transistor including a first gate electrode disposed on a first gate insulating layer having an inverse taper shape, a buffer layer disposed to cover the first gate electrode, an active layer disposed on the buffer layer, a second gate insulating layer disposed to cover the active layer, and a second gate electrode disposed on the second gate insulating layer and having a taper shape.

In one or more embodiments, the gate driving circuit may include a first transistor switched by a second gate clock signal and supplying a gate start signal to a Q1 node, a second transistor switched by a first gate clock signal and allowing one of a source electrode and a drain electrode to be electrically connected to the Q1 node, a third transistor switched by a voltage of a QB node and supplying a gate high voltage to one of the source electrode and the drain electrode of the second transistor, a fourth transistor switched by a second gate clock signal and supplying a gate low voltage to the QB node, a fifth transistor switched by a voltage of the Q1 node and supplying the second gate clock signal to the QB node, a sixth transistor transferring the first gate clock signal to an output node by a voltage of a Q2 node, a seventh transistor transferring the gate high voltage to the output node by a voltage of the QB node, an auxiliary transistor controlled by the gate low voltage and connecting the Q1 node and the Q2 node, a first capacitor connected between the Q2 node and the output node, and a second capacitor connected between the QB node and a terminal to which the gate high voltage is input. In this implementation, the fifth transistor may be configured as the double gate transistor.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure.

What is claimed is:

1. A double gate transistor comprising:
a first gate electrode on a substrate, the first gate electrode having an inverse taper shape;
a first gate insulating layer disposed such that the first gate insulating layer covers the first gate electrode;
an active layer on the first gate insulating layer;
a second gate insulating layer disposed such that the second gate insulating layer covers the active layer; and
a second gate electrode on the second gate insulating layer, the second gate electrode having a taper shape,
wherein the active layer comprises a channel region at a location overlapping with the first gate electrode and the second gate electrode.

2. The double gate transistor of claim 1, wherein the first gate electrode comprises:
a first-first gate region on the substrate; and
a first-second gate region on the first-first gate region, the first-second gate region having the inverse taper shape.

3. The double gate transistor of claim 2, wherein a width of the first-first gate region is greater than a width of the second gate electrode.

4. The double gate transistor of claim 1, wherein the first gate electrode comprises:
a first-first gate region on the substrate, the first-first gate region having a taper shape; and
a first-second gate region on the first-first gate region, the first-second gate region having an inverse taper shape.

5. The double gate transistor of claim 1, wherein the first gate electrode comprises:
a first-first gate region on the substrate, the first-first gate region having an inverse taper shape; and
a first-second gate region on the first-first gate region, the first-second gate region having an inverse taper shape, and
wherein a width of the first-second gate region is greater than a width of the first-first gate region.

6. The double gate transistor of claim 5, wherein the first-first gate region comprises copper and the first-second gate region comprises titanium or a molybdenum-titanium alloy.

7. The double gate transistor of claim 1, wherein the first gate electrode comprises:
a first-first gate region on the substrate, the first-first gate region having a taper shape;
a first-second gate region on the first-first gate region, the first-second gate region having an inverse taper shape; and
a first-third gate region on the first-second gate region, the first-third gate region having an inverse taper shape, and
wherein a width of the first-third gate region is greater than a width of the first-second gate region.

8. The double gate transistor of claim 7, wherein:
the first-first gate region comprises titanium or a molybdenum-titanium alloy;
the first-second gate region comprises copper; and
the first-third gate region comprises titanium or a molybdenum-titanium alloy.

9. The double gate transistor of claim 1, wherein the active layer further comprises:
conductive semiconductor regions located on both sides of the channel region, the conductive semiconductor regions doped with an impurity; and
diffusion regions between the channel region and each of the conductive semiconductor regions, and
wherein the active layer comprises a plurality of regions having different mobilities.

10. The double gate transistor of claim 9, wherein the active layer comprises:
a first active region on the substrate, the first active region having a first mobility;
a second active region on the first active region, the second active region having a second mobility; and
a third active region on the second active region, the third active region having a third mobility.

11. The double gate transistor of claim 10, wherein the second mobility is greater than each of the first mobility and the third mobility.

12. The double gate transistor of claim 10, wherein the third mobility is greater than each of the first mobility and the second mobility.

13. The double gate transistor of claim 1, wherein the channel region comprises:
a first channel region adjacent to the first gate electrode; and
a second channel region adjacent to the second gate electrode, and
wherein a width of the first channel region is greater than a width of the second channel region.

14. The double gate transistor of claim 13, wherein the width of the first channel region is greater than a width of the second gate electrode.

15. The double gate transistor of claim 13, wherein the width of the second channel region is less than a width of the first gate electrode.

16. The double gate transistor of claim 1, wherein a ratio of a tapered angle of the first gate electrode and a tapered angle of the second gate electrode is proportional to a ratio of a first capacitance between the active layer and the first gate electrode and a second capacitance between the active layer and the second gate electrode.

17. A display device comprising:
a display panel including a plurality of subpixels;
a gate driving circuit configured to supply at least one gate signal to the display panel;
a data driving circuit configured to supply at least one data signal to the display panel; and
a timing controller configured to control the gate driving circuit and the data driving circuit,
wherein at least one of the plurality of subpixels comprises at least one double gate transistor, the at least one double gate transistor comprising:
a first gate electrode on a substrate, the first gate electrode having an inverse taper shape;
a first gate insulating layer disposed such that the first gate insulating layer covers the first gate electrode;
an active layer on the first gate insulating layer;
a second gate insulating layer disposed such that the second gate insulating layer covers the active layer; and
a second gate electrode disposed on the second gate insulating layer, the second gate electrode having a tapered shape.

18. The display device of claim 17, wherein at least one subpixel from the plurality of subpixels comprises:
a light emitting element;
a driving transistor that provides current to the light emitting element;
a first transistor connected between a gate node and a drain node of the driving transistor;
a second transistor connected between a data line and a source node of the driving transistor;
a third transistor connected between a driving voltage line and the source node of the driving transistor;
a fourth transistor connected between the drain node of the driving transistor and an anode electrode of the light emitting element;
a fifth transistor connected between the gate node of the driving transistor and an initialization voltage line;
a sixth transistor connected between an anode reset voltage line and the anode electrode of the light emitting element; and
a storage capacitor connected between the driving voltage line and the fifth transistor, and
wherein the first transistor or the fifth transistor is configured as the double gate transistor.

19. A display device comprising:
a display panel including a plurality of subpixels are disposed;
a gate driving circuit configured to supply at least one gate signal to the display panel;
a data driving circuit configured to supply at least one data signal to the display panel; and
a timing controller configured to control the gate driving circuit and the data driving circuit,
wherein the gate driving circuit comprises at least one double gate transistor, the at least one double gate transistor comprising:
a first gate electrode disposed on a substrate, the first gate electrode having an inverse taper shape;
a first gate insulating layer disposed such that the first gate insulating layer covers the first gate electrode;
an active layer on the first gate insulating layer;
a second gate insulating layer disposed such that the second gate insulating layer covers the active layer; and
a second gate electrode on the second gate insulating layer and having a tapered shape.

20. The display device of claim 19, wherein the gate driving circuit comprises:
a first transistor switched by a second gate clock signal and supplying a gate start signal to a Q1 node;
a second transistor switched by a first gate clock signal and allowing one of a source electrode and a drain electrode to be electrically connected to the Q1 node;
a third transistor switched by a voltage of a QB node and supplying a gate high voltage to one of the source electrode and the drain electrode of the second transistor;
a fourth transistor switched by a second gate clock signal and supplying a gate low voltage to the QB node;
a fifth transistor switched by a voltage of the Q1 node and supplying the second gate clock signal to the QB node;
a sixth transistor transferring the first gate clock signal to an output node by a voltage of a Q2 node;
a seventh transistor transferring the gate high voltage to the output node by a voltage of the QB node;
an auxiliary transistor controlled by the gate low voltage and connecting the Q1 node and the Q2 node;
a first capacitor connected between the Q2 node and the output node; and
a second capacitor connected between the QB node and a terminal to which the gate high voltage is input, and
wherein the fifth transistor is configured as the at least one double gate transistor.
